(19) United States
(12) Patent Application Publication
(10) Pub. No.: US 2014/0066656 A1
(43) Pub. Date: Mar. 6, 2014

(54) SPIRO COMPOUNDS AND THEIR USE IN ORGANIC ELECTRONICS APPLICATIONS AND DEVICES

(71) Applicant: BASF SE, Ludwigshafen (DE)

(72) Inventors: Ingmar BRUDER, Mutterstadt (DE); Ruediger Sens, Ludwigshafen (DE); Robert Send, Karlsruhe (DE); Henrike Wonneberger, Mannheim (DE); Hermann Bergmann, Osnabrueck (DE); Vytautas Getautis, Kaunas (LT); Maryte Daskeviciene, Jonava (LT); Tadas Malinauskas, Kaunas (LT); Daiva Tomkute-Luksiene, Kaisiadoriai (LT)

(73) Assignee: BASF SE, Ludwigshafen (DE)

(21) Appl. No.: 14/016,514

(22) Filed: Sep. 3, 2013

Related U.S. Application Data
(60) Provisional application No. 61/696,346, filed on Sep. 4, 2012.

(51) Int. Cl. H01L 51/00

(52) U.S. Cl. CPC H01L 51/006
USPC 564/322

(57) ABSTRACT

The present invention relates 9,9′-spirobifluorene compounds of general formula I

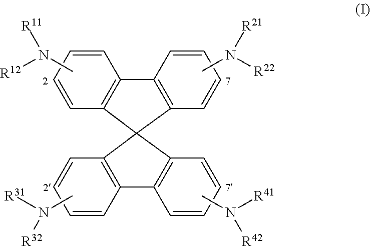

wherein the variables R¹¹, R¹², R²¹, R²², R³¹, R³², R⁴¹ and R⁴² independently of each other have the meaning of aryl or hetaryl, with the proviso that not all of the radicals R¹¹, R¹², R²¹, R²², R³¹, R³², R⁴¹ and R⁴² are identical,
to the use of compounds of general formula I in organic electronics applications, especially in organic field effect transistors, in organic photodetectors and organic solar cells, specifically in dye-sensitized solar cells and bulk heterojunction solar cells, and
to an organic field effect transistor, a dye-sensitized solar cell and a bulk heterojunction solar cell comprising compounds of general formula I.

The present invention relates 9,9′-spirobifluorene compounds of general formula I

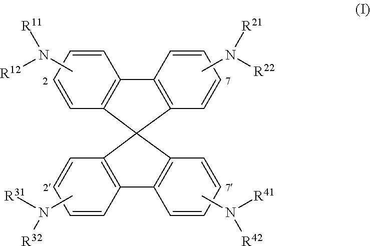

wherein the variables R¹¹, R¹², R²¹, R²², R³¹, R³², R⁴¹ and R⁴² independently of each other have the meaning of aryl or hetaryl, with the proviso that not all of the radicals R¹¹, R¹², R²¹, R²², R³¹, R³², R⁴¹ and R⁴² are identical,
to the use of compounds of general formula I in organic electronics applications, especially in organic field effect transistors, in organic photodetectors and organic solar cells, specifically in dye-sensitized solar cells and bulk heterojunction solar cells, and
to an organic field effect transistor, a dye-sensitized solar cell and a bulk heterojunction solar cell comprising compounds of general formula I.

Dye-sensitized solar cells (“DSCs”) are one of the most efficient alternative solar cell technologies at present. In a liquid variant of this technology, efficiencies of up to 11% have been achieved to date (e.g. Gratzel M. et al., J. Photochem. Photobio. C, 2003, 4, 145; Chiba et al., Japanese Journal of Appl. Phys., 2006, 45, L638-L640).

The construction of a DSC is generally based on a glass substrate, which is coated with a transparent conductive layer, the working electrode. An n-conductive metal oxide is generally applied to this electrode or in the vicinity thereof, for example an approx. 2-20 μm-thick nanoporous titanium dioxide layer (TiO₂). On the surface thereof, in turn, a monolayer of a light-sensitive dye, for example a ruthenium complex, is typically adsorbed, which can be converted to an excited state by light absorption. The counterelectrode may optionally have a catalytic layer of a metal, for example platinum, with a thickness of a few μm. The area between the two electrodes is filled with a redox electrolyte, for example a solution of iodine (I₂) and lithium iodide (LiI).

The function of the DSC is based on the fact that light is absorbed by the dye, and electrons are transferred from the excited dye to the n-semiconductive metal oxide semiconductor and migrate thereon to the anode, whereas the electrolyte ensures that the charges are balanced via the cathode. The n-semiconductive metal oxide, the dye and the (usually liquid) electrolyte are thus the most important constituents of the DSC, though cells comprising liquid electrolyte in many cases suffer from nonoptimal sealing, which leads to stability problems. Various materials have therefore been studied for their suitability as solid electrolytes/p-semiconductors.

Various inorganic p-semiconductors such as CuI, CuBr.3(S(C₄H₉)₂) or CuSCN have found use to date in solid-stage DSCs. With CuI-based, solid DSCs, for example, efficiencies of more than 7% have been reported by Hitoshi Sakamoto et al. (Organic Electronics 13 (2012), 514-518).

Solid DSCs comprising fluorine and tin difluoride doped CsSnl3 as hole conducting material and displaying efficiencies of around 10% were reported by In Chung et al. (Nature Vol. 485, May 24, 2012, 486-490)

Organic polymers are also used as solid p-semiconductors. Examples thereof include polypyrrole, poly(3,4-ethylenedioxythiophene), carbazole-based polymers, polyaniline, poly(4-undecyl-2,2′-bithiophene), poly(3-octylthiophene), poly(triphenyldiamine) and poly(N-vinylcarbazole). In the case of poly(N-vinylcarbazole), the efficiencies reach up to 2%; with a PEDOT (poly(3,4-ethylenedioxythiophene), polymerized in situ, an efficiency of 2.9% was even achieved (Xia et al. J. Phys. Chem. C 2008, 112, 11569), though the polymers are typically not used in pure form but usually in a mixture with additives. In addition, a concept in which polymeric p-semiconductors are bonded directly to an Ru dye is also presented (Peter, K., Appl. Phys. A 2004, 79, 65).

High efficiencies are also achieved with low molecular weight organic p-semiconductors. WO 98/48433 A1, for example, reports the use of the organic compound 2,2′,7,7′-tetrakis(N,N-di-p-methoxyphenyl-amine)-9,9′-spirobifluorene (“spiro-MeOTAD”) in DSCs as hole transporting material.

Spiro-MeOTAD is likewise examined by Snaith, H. J.; Moule, A. J.; Klein, C.; Meerholz, K.; Friend, R. H.; Gratzel (M. Nano Lett.; (Letter); 2007; 7(11); 3372-3376) as hole transporting material in DSCs.

Further spiro compounds as hole transporting and hole injecting materials, mainly applied in organic light emitting diodes (“OLEDs”), are described in WO 2011/116869 A1.

Studies by C. Jäger et al. (Proc. SPIE 4108, 104-110 (2001)) show that spiro-MeOTAD is present in semicrystalline form, and there is a strong tendency of (re)crystallization in the processed form, i.e. in the DSC.

In addition, the solubility in customary process solvents is relatively low, which leads to a correspondingly low degree of pore filling.

Durrant et al., Adv. Func. Mater. 2006, 16, 1832-1838 state that, in many cases, the photocurrent is directly dependent on the yield in the hole transition from the oxidized dye to the solid p-conductor. This depends essentially on two factors: first on the degree of penetration of the p-semiconductor into the oxide pores, and second on the thermodynamic driving force for the charge transfer, i.e. especially on the difference in the free enthalpy AG between dye and p-conductor.

Recent developments in organic photovoltaics have been in the direction of the so-called “bulk heterojunction” (“BHJ”) solar cells: in this case, the photoactive layer comprises the acceptor and donor compound(s) as a bicontinuous phase. As a result of photoinduced charge transfer from the excited state of the donor compound to the acceptor compound, owing to the spatial proximity of the compounds, a rapid charge separation compared to other relaxation procedures takes place, and the holes and electrons which arise are removed via the corresponding electrodes. Between the electrodes and the photoactive layer, further layers, for example hole or electron transport layers, are often applied in order to increase the efficiency of such cells.

To date, the donor materials used in such BHJ cells have usually been polymers, for example polyvinylphenylenes or polythiophenes, or dyes from the class of the phthalocyanines, e.g. zinc phthalocyanine or vanadyl phthalocyanine, and the acceptor materials used have been fullerene and fullerene derivatives and also various perylenes. Photoactive layers composed of the donor/acceptor pairs poly(3-hexyl-thiophene) (“P3HT”)/[6,6]-phenyl-C₆₁-butyric acid methyl ester (“PCBM”), poly(2-methoxy-5-(3,7-dimethyloctyloxy)-1,4-phenylenevinylene) (“OCiCio-PPV”)/PCBM and zinc phthalocyanine/fullerene have been and are being researched intensively.

It was therefore an object of the present invention to provide further compounds which can be used advantageously as p-semiconductors in solar cells, especially in DSCs and BHJ cells. With regard to their profile of properties, these compounds should have good hole-conducting properties, have only a very low tendency, if any, to crystallize, and have good solubility in the solvents used customarily.

Accordingly, compounds of general formula I

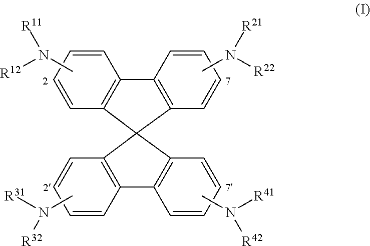

have been synthesized,
wherein the variables R¹¹, R¹², R²¹, R²², R³¹, R³², R⁴¹ and R⁴² independently of each other have the meaning of aryl or hetaryl, with the proviso that not all of the radicals R¹¹, R¹², R²¹, R²², R³¹, R³², R⁴¹ and R⁴² are identical.

Preference is given to compounds of general formula I wherein in general formula I the moieties N(R¹¹R¹²), N(R²¹R²²), N(R³¹R³²) and N(R⁴¹R⁴²) are bound to the 2, 2′,7 and 7′ positions of the 9,9′-spirobifluorene skeleton.

Specifically preferred compounds, also with regard to the aforementioned preference, are those wherein in general formula I the variables R¹¹, R¹², R²¹, R²², R³¹, R³², R⁴¹ and R⁴² independently of each other are moieties of formulae Ia or Ib

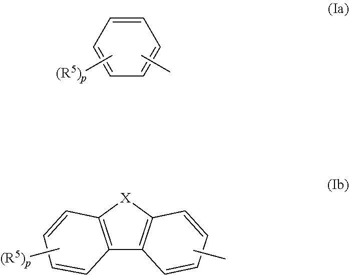

wherein the variables have the following meaning
R⁵ hydrogen, alkyl, aryl, alkoxy, alkylthio or —NR⁶R⁷, where in case of two or more substituents (p equal or greater than 2) these may be identical or different,
p 0, 1, 2, 3, 4 or 5,
X C(R⁸R⁹)₂, NR¹⁰, oxygen or sulfur,
   and
R⁶ to R¹⁹ hydrogen, alkyl, cycloalkyl, aryl or hetaryl.

Further preference is given to compounds, also with regard to the abovementioned preferences, wherein in general formula I the variables R¹¹, R²¹, R³¹ and R⁴¹ are identical to each other and the variables R¹², R²², R³² and R⁴² are identical to each other. As the general proviso still holds that not all of the variables R¹¹, R¹², R²¹, R²², R³¹, R³², R⁴¹ and R⁴² be identical, thus both sets R¹¹, R²¹, R³¹ and R⁴¹ and R¹², R²², R³² and R⁴² of variables are different from each other.

Furthermore, not only compounds with specific substituents R¹¹, R¹², R²¹, R²², R³¹, R³², R⁴¹ and R⁴² shall be embraced by the instant invention, but also mixtures of compounds with randomized distribution of the substituents R¹¹, R¹², R²¹, R²², R³¹, R³², R⁴¹ and R⁴²_{.}

One route of preparing compounds of formula I of the instant application comprises reacting compounds of general formula IIa

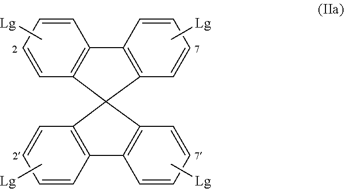

with a mixture of appropriate amines of formulae HNR¹¹R¹², HNR²¹R²², HNR³¹R³² and HNR⁴¹R⁴² in the presence of a palladium containing catalyst under the conditions of the Buchwald-Hartwig amination reaction, where the variables R¹¹, R¹², R²¹, R²², R³¹, R³², R⁴¹ and R⁴² have the aforementioned meaning and Lg denotes a leaving group typically known to a person skilled in the art. Examples of such groups Lg are given below. Typically, this reaction leads to a mixture of compounds of formula I with randomized distribution of the corresponding substituents —NR¹¹R¹², —NR²¹R²², —NR³¹R³² and —NR⁴¹R⁴².

Compounds of formula I following the abovementioned proviso that not all of the radicals R¹¹, R¹², R²¹, R²², R³¹, R³², R⁴¹ and R⁴² are identical and at the same time do not display randomization of the substituents are represented by the following formula II

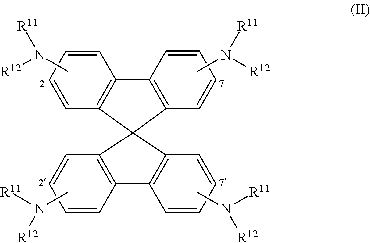

wherein the variables R¹¹ and R¹² differ from each other and have the meaning aryl or hetaryl.

Similar to the aforementioned synthesis these compounds of formula II can be prepared, for example, by reacting a compound of general formula IIa

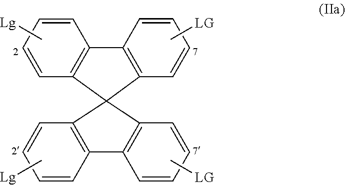

with a compound of general formula IIb

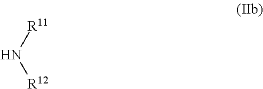

in the presence of a palladium containing catalyst under the conditions of the Buchwald-Hartwig amination reaction, wherein the variables have the following meaning
R¹¹, R¹² different from each other aryl or hetaryl
   and
Lg leaving group.

In general, the leaving group Lg can be any group known to a person skilled in the art as being prone to easily leave the molecule. Typically, Lg consists of or comprises strongly electron-withdrawing atoms or moieties and, thus, is normally split off as anionic species.

Favorable groups Lg are chlorine, bromine, iodine, brosylate, nosylate, tosylate, mesylate and triflate which, in view of the aforesaid, leave the molecule as chloride, bromide, iodide, brosylate, nosylate, tosylate, mesylate or triflate anion.

The structure of the brosylate, nosylate and tosylate are, in respective order, as follows:

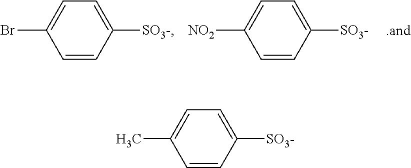

According to the aforementioned synthetic routes specifically preferred compounds of formula I or formula II can be prepared, wherein the variables R¹¹, R¹², R²¹, R²², R³¹, R³², R⁴¹ and R⁴² and the variables R¹¹ and R¹², respectively, are independently of each other moieties of formulae Ia or Ib

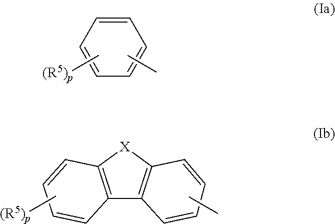

and wherein the variables in formula Ia and Ib have the following meaning
R⁵ hydrogen, alkyl, aryl, alkoxy, alkylthio or —NR⁶R⁷, where in case of two or more substituents (p equal or greater than 2) these may be identical or different,
p 0, 1, 2, 3, 4 or 5,
X C(R⁸R⁹)₂, NR¹⁰, oxygen or sulfur,
   and
R⁶ to R¹⁰ hydrogen, alkyl, cycloalkyl, aryl or hetaryl.

The Buchwald-Hartwig amination reaction is a well established synthetic route and the reaction conditions can easily be determined by a person skilled in the art. Conversion of aryl bromides to arylamines is specifically addressed in the publication by Guram, A. S.; Rennels, R. A.; Buchwald, S. L. (1995), “A Simple Catalytic Method for the Conversion of Aryl Bromides to Arylamines”, Angewandte Chemie International Edition 34 (12): 1348-1350.

The abovementioned compounds of general formula I and II and their preferred embodiments are particularly suited for organic electronics applications, especially in organic field effect transistors, dye-sensitized solar cells and bulk heterojunction solar cells with generally low tendency of crystallization and thus enhanced long term stability of the resulting organic electronic devices. In the aforementioned devices these compounds typically function as hole transporting materials.

Thus, another objective of the instant invention is the use of compounds of general formula I and their preferred embodiments in organic electronics applications. Specifically, the compounds of general formula I and their preferred embodiments are used in organic field effect transistors, organic solar cells and organic photodetectors.

Another preferred objective of the instant invention is the use of compounds of general formula I and their preferred embodiments in dye-sensitized solar cells and bulk heterojunction solar cells.

Further objectives of the instant invention pertain to field effect transistor, dye-sensitized solar cells and bulk heterojunction solar cells comprising compounds of general formula I and their preferred embodiments.

### BRIEF DESCRIPTION OF THE DRAWINGS

FIG. 1 shows a comparison of the lifetime of DSCs comprising hole transporting materials HTM1, HTM2 and HTM3 according to the instant invention versus a DSC comprising spiro-MeOTAD. In the case of HTM1, HTM2 and HTM3 the long term stability of the corresponding DSCs is significantly enhanced over the DSC comprising spiro-MeOTAD. All DSCs were sealed and constantly kept at 60° C. and 30% humidity after fabrication.

In another series of experiments solar cells comprising spiro-MeOTAD as hole transporting material were kept at 100° C. for 240 minutes to elucidate the cause of the reduced lifetime in cells with spiro-MeOTAD (cf. FIGS. 2 and 3).

FIG. 2 shows an example of the initial condition, i.e. at 25° C. after fabrication and before heat treatment, of the spiro-MeOTAD coating on the silver back electrode of the cells. No spiro-MeOTAD crystals were visible under an optical microscope with crossed polarizers.

FIG. 3 shows an example of the condition after heating for 240 min at 100° C. Spiro-MeOTAD crystals became clearly visible under the optical microscope and the cell efficiencies were dramatically reduced down to 0.02%. The photo is taken after cooling to 25° C.

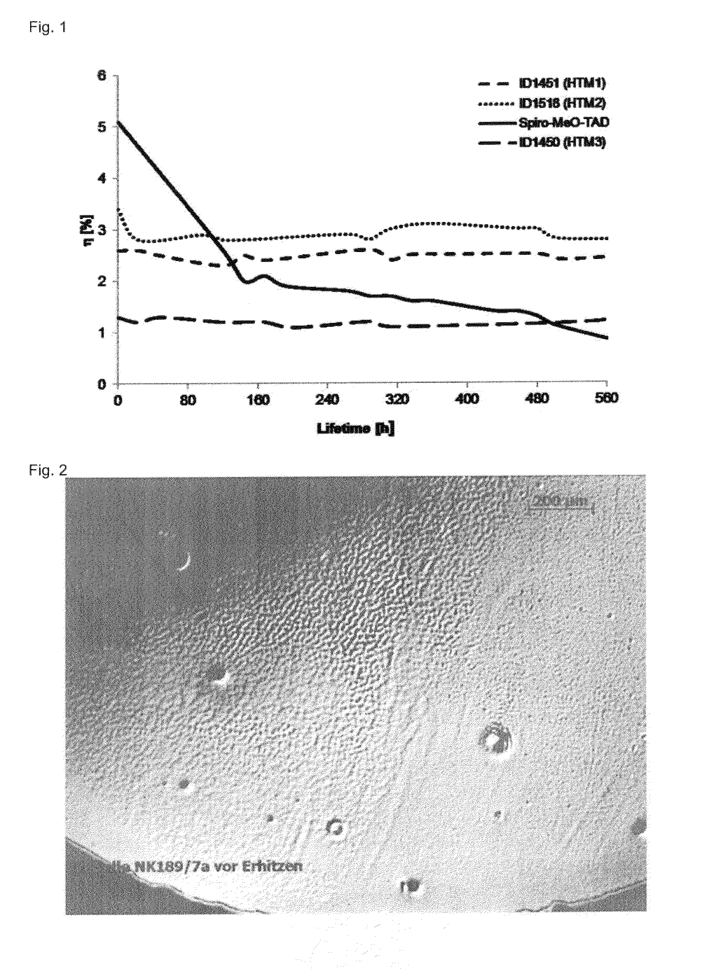

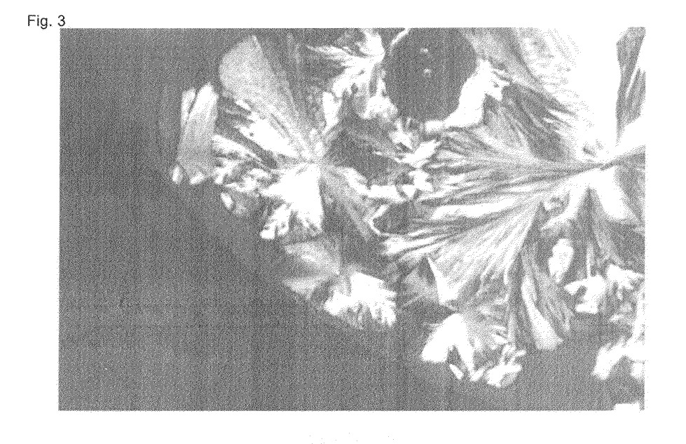

In the context of the present invention, alkyl, aryl or heteroaryl represents unsubstituted or substituted alkyl, unsubstituted or substituted aryl or unsubstituted or substituted heteroaryl. Alkyl comprises straight-chain or branched alkyl. Alkyl is preferably C₁-C₃₀-alkyl, especially C₁-C₂₀-alkyl and most preferably C₁-C₁₂-alkyl. Examples of alkyl groups are especially methyl, ethyl, n-propyl, isopropyl, n-butyl, isobutyl, sec-butyl, tert-butyl, n-pentyl, n-hexyl, n-heptyl, n-octyl, n-nonyl, n-decyl, n-undecyl, n-dodecyl, n-tridecyl, n-tetradecyl, n-hexadecyl, n-octadecyl and n-eicosyl.

Further examples of branched alkyl groups can be represented by the following formula

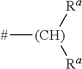

in which
# denotes a bonding site, and
R^{a} is selected from C₁ to C₂₈-alkyl, where the sum of the carbon atoms of the R⁹ radicals is an integer from 2 to 29.

In the formula above, the R^{a} radicals are preferably selected from C₁- to C₁₂-alkyl, especially C₁- to C₈-alkyl.

Preferred branched alkyl radicals of the above formula are, for example:

1-ethylpropyl, 1-methylpropyl, 1-propylbutyl, 1-ethylbutyl, 1-methylbutyl, 1-butylpentyl, 1-propylpentyl, 1-ethylpentyl, 1-methylpentyl, 1-pentylhexyl, 1-butylhexyl, 1-propylhexyl, 1-ethylhexyl, 1-methylhexyl, 1-hexylheptyl, 1-pentylheptyl, 1-butylheptyl, 1-propylheptyl, 1-ethylheptyl, 1-methylheptyl, 1-heptyloctyl, 1-hexyloctyl, 1-pentyloctyl, 1-butyloctyl, 1-propyloctyl, 1-ethyloctyl, 1-methyloctyl, 1-octylnonyl, 1-heptylnonyl, 1-hexylnonyl, 1-pentylnonyl, 1-butylnonyl, 1-propylnonyl, 1-ethylnonyl, 1-methylnonyl, 1-nonyldecyl, 1-octyldecyl, 1-heptyldecyl, 1-hexyldecyl, 1-pentyldecyl, 1-butyldecyl, 1-propyldecyl, 1-ethyldecyl, 1-methyldecyl, 1-decylundecyl, 1-nonylundecyl, 1-octylundecyl, 1-heptylundecyl, 1-hexylundecyl, 1-pentylundecyl, 1-butylundecyl, 1-propylundecyl, 1-ethylundecyl, 1-methylundecyl, 1-undecyldodecyl, 1-decyldodecyl, 1-nonyldodecyl, 1-octyldodecyl, 1-heptyldodecyl, 1-hexyldodecyl, 1-pentyldodecyl, 1-butyldodecyl, 1-propyldodecyl, 1-ethyldodecyl, 1-methyldodecyl, 1-dodecyltridecyl, 1-undecyltridecyl, 1-decyltridecyl, 1-nonyltridecyl, 1-octyltridecyl, 1-heptyltridecyl, 1-hexyltridecyl, 1-pentyltridecyl, 1-butyltridecyl, 1-propyltridecyl, 1-ethyltridecyl, 1-methyltridecyl, 1-tridecyltetradecyl, 1-undecyltetradecyl, 1-decyltetradecyl, 1-nonyltetradecyl, 1-octyltetradecyl, 1-heptyltetradecyl, 1-hexyltetradecyl, 1-pentyltetradecyl, 1-butyltetradecyl, 1-propyltetradecyl, 1-ethyltetradecyl, 1-methyltetradecyl, 1-pentadecylhexadecyl, 1-tetradecylhexadecyl, 1-tridecylhexadecyl, 1-dodecylhexadecyl, 1-undecylhexadecyl, 1-decylhexadecyl, 1-nonylhexadecyl, 1-octylhexadecyl, 1-heptylhexadecyl, 1-hexylhexadecyl, 1-pentylhexadecyl, 1-butylhexadecyl, 1-propylhexadecyl, 1-ethylhexadecyl, 1-methylhexadecyl, 1-hexadecyloctadecyl, 1-pentadecyloctadecyl, 1-tetradecyloctadecyl, 1-tridecyloctadecyl, 1-dodecyloctadecyl, 1-undecyloctadecyl, 1-decyloctadecyl, 1-nonyloctadecyl, 1-octyloctadecyl, 1-heptyloctadecyl, 1-hexyloctadecyl, 1-pentyloctadecyl, 1-butyloctadecyl, 1-propyloctadecyl, 1-ethyloctadecyl, 1-methyloctadecyl, 1-nonadecyleicosanyl, 1-octadecyleicosanyl, 1-heptadecyleicosanyl, 1-hexadecyleicosanyl, 1-pentadecyleicosanyl, 1-tetradecyleicosanyl, 1-tridecyleicosanyl, 1-dodecyleicosanyl, 1-undecyleicosanyl, 1-decyleicosanyl, 1-nonyleicosanyl, 1-octyleicosanyl, 1-heptyleicosanyl, 1-hexyleicosanyl, 1-pentyleicosanyl, 1-butyleicosanyl, 1-propyleicosanyl, 1-ethyleicosanyl, 1-methyleicosanyl, 1-eicosanyldocosanyl, 1-nonadecyldocosanyl, 1-octadecyldocosanyl, 1-heptadecyldocosanyl, 1-hexadecyldocosanyl, 1-pentadecyldocosanyl, 1-tetradecyldocosanyl, 1-tridecyldocosanyl, 1-undecyldocosanyl, 1-decyldocosanyl, 1-nonyldocosanyl, 1-octyldocosanyl, 1-heptyldocosanyl, 1-hexyldocosanyl, 1-pentyldocosanyl, 1-butyldocosanyl, 1-propyldocosanyl, 1-ethyldocosanyl, 1-methyldocosanyl, 1-tricosanyltetracosanyl, 1-docosanyltetracosanyl, 1-nonadecyltetracosanyl, 1-octadecyltetracosanyl, 1-heptadecyltetracosanyl, 1-hexadecyltetracosanyl, 1-pentadecyltetracosanyl, 1-pentadecyltetracosanyl, 1-tetradecyltetracosanyl, 1-tridecyltetracosanyl, 1-dodecyltetracosanyl, 1-undecyltetracosanyl, 1-decyltetracosanyl, 1-nonyltetracosanyl, 1-octyltetracosanyl, 1-heptyltetracosanyl, 1-hexyltetracosanyl, 1-pentyltetracosanyl, 1-butyltetracosanyl, 1-propyltetracosanyl, 1-ethyltetracosanyl, 1-methyltetracosanyl, 1-heptacosanyloctacosanyl, 1-hexacosanyloctacosanyl, 1-pentacosanyloctacosanyl, 1-tetracosanyloctacosanyl, 1-tricosanyloctacosanyl, 1-docosanyloctacosanyl, 1-nonadecyloctacosanyl, 1-octadecyloctacosanyl, 1-heptadecyloctacosanyl, 1-hexadecyloctacosanyl, 1-hexadecyloctacosanyl, 1-pentadecyloctacosanyl, 1-tetradecyloctacosanyl, 1-tridecyloctacosanyl, 1-dodecyloctacosanyl, 1-undecyloctacosanyl, 1-decyloctacosanyl, 1-nonyloctacosanyl, 1-octyloctacosanyl, 1-heptyloctacosanyl, 1-hexyloctacosanyl, 1-pentyloctacosanyl, 1-butyloctacosanyl, 1-propyloctacosanyl, 1-ethyloctacosanyl, 1-methyloctacosanyl.

Alkyl also comprises alkyl radicals whose carbon chains may be interrupted by one or more nonadjacent groups selected from oxygen, sulfur, —CO—, —NR^{b}—, —SO— and/or —SO₂— where R^{b} is preferably hydrogen, unsubstituted straight-chain or branched alkyl as described before or unsubstituted aryl as described below.

Substituted alkyl groups may, depending on the length of the alkyl chain, have one or more (e.g. 1, 2, 3, 4, 5 or more than 5) substituents. These are preferably each independently selected from cycloalkyl, heterocycloalkyl, aryl, hetaryl, fluorine, chlorine, bromine, cyano and nitro.

Aryl-substituted alkyl radicals (aralkyl) have at least one unsubstituted or substituted aryl group, as defined below. The alkyl group of the aralkyl radical may bear at least one further substituent and/or be interrupted by one or more nonadjacent groups selected from oxygen, sulfur, —CO—, —NR^{b}—, —SO— and/or —SO₂— where R^{b} is preferably hydrogen, unsubstituted straight-chain or branched alkyl as described before or unsubstituted aryl as described below. Arylalkyl is preferably phenyl-C₁-C₁₀-alkyl, more preferably phenyl-C₁-C₄-alkyl, for example benzyl, 1-phenethyl, 2-phenethyl, 1-phenprop-1-yl, 2-phenprop-1-yl, 3-phenprop-1-yl, 1-phenbut-1-yl, 2-phenbut-1-yl, 3-phenbut-1-yl, 4-phenbut-1-yl, 1-phenbut-2-yl, 2-phenbut-2-yl, 3-phenbut-2-yl, 4-phenbut-2-yl, 1-(phenmeth)eth-1-yl, 1-(phenmethyl)-1-(methyl)eth-1-yl or -(phenmethyl)—1-(methyl)prop-1-yl; preferably benzyl and 2-phenethyl.

Halogen-substituted alkyl groups (haloalkyl) comprise a straight-chain or branched alkyl group in which at least one hydrogen atom or all hydrogen atoms are replaced by halogen. The halogen atoms are preferably selected from fluorine, chlorine and bromine, especially fluorine and chlorine. Examples of haloalkyl groups are especially chloromethyl, bromomethyl, dichloromethyl, trichloromethyl, fluoromethyl, difluoromethyl, trifluoromethyl, chlorofluoromethyl, dichlorofluoromethyl, chlorodifluoromethyl, 1-chloroethyl, 1-bromoethyl, 1-fluoroethyl, 2-fluoroethyl, 2,2-difluoroethyl, 2,2,2-trifluoroethyl, 2-chloro-2-fluoroethyl, 2-chloro-2,2-difluoroethyl, 2,2-dichloro-2-fluoroethyl, 2,2,2-trichloroethyl, pentafluoroethyl, 2-fluoropropyl, 3-fluoropropyl, 2,2-difluoropropyl, 2,3-difluoropropyl, 2-chloropropyl, 3-chloropropyl, 2,3-dichloropropyl, 2-bromopropyl, 3-bromopropyl, 3,3,3-trifluoropropyl, 3,3,3-trichloropropyl, —CH₂—C₂F₅, —CF₂—C₂F₅, —CF(CF₃)₂, 1-(fluoromethyl)-2-fluoroethyl, 1-(chloromethyl)-2-chloroethyl, 1-(bromomethyl)-2-bromoethyl, 4-fluorobutyl, 4-chlorobutyl, 4-bromobutyl, nonafluorobutyl, 5-fluoro-1-pentyl, 5-chloro-1-pentyl, 5-bromo-1-pentyl, 5-iodo-1-pentyl, 5,5,5-trichloro-1-pentyl, undecafluoropentyl, 6-fluoro-1-hexyl, 6-chloro-1-hexyl, 6-bromo-1-hexyl, 6-iodo-1-hexyl, 6,6,6-trichloro-1-hexyl or dodecafluorohexyl.

The above remarks regarding unsubstituted or substituted alkyl also apply to unsubstituted or substituted alkoxy and unsubstituted or substituted dialkylamino.

Specific examples of unsubstituted and substituted alkyl radicals which may be interrupted by one or more nonadjacent groups selected from oxygen, sulfur, —NR^{b}—, —CO—, —SO— and/or —SO₂— are:

methyl, ethyl, n-propyl, isopropyl, n-butyl, isobutyl, sec-butyl, tert-butyl, n-pentyl, n-hexyl, n-heptyl, n-octyl, n-nonyl, n-decyl, n-undecyl, n-dodecyl, n-tridecyl, n-tetradecyl, n-hexadecyl, n-octadecyl and n-eicosyl, 2-methoxyethyl, 2-ethoxyethyl, 2-propoxyethyl, 2-butoxyethyl, 3-methoxypropyl, 3-ethoxypropyl, 3-propoxypropyl, 3-butoxypropyl, 4-methoxybutyl, 4-ethoxybutyl, 4-propoxybutyl, 3,6-dioxaheptyl, 3,6-dioxaoctyl, 4,8-dioxanonyl, 3,7-dioxaoctyl, 3,7-dioxanonyl, 4,7-dioxaoctyl, 4,7-dioxanonyl, 2- and 4-butoxybutyl, 4,8-dioxadecyl, 3,6,9-trioxadecyl, 3,6,9-trioxaundecyl, 3,6,9-trioxadodecyl, 3,6,9,12-tetraoxamidecyl and 3,6,9,12-tetraoxatetradecyl;

2-methylthioethyl, 2-ethylthioethyl, 2-propylthioethyl, 2-butylthioethyl, 3-methylthiopropyl, 3-ethylthiopropyl, 3-propylthiopropyl, 3-butylthiopropyl, 4-methylthiobutyl, 4-ethylthiobutyl, 4-propylthiobutyl, 3,6-dithiaheptyl, 3,6-dithiaoctyl, 4,8-dithianonyl, 3,7-dithiaoctyl, 3,7-dithianonyl, 2- and 4-butylthiobutyl, 4,8-dithiadecyl, 3,6,9-trithiadecyl, 3,6,9-trithiaundecyl, 3,6,9-trithiadodecyl, 3,6,9,12-tetrathiamidecyl and 3,6,9,12-tetrathiatetradecyl;

2-monomethyl- and 2-monoethylaminoethyl, 2-dimethylaminoethyl, 2- and 3-dimethylaminopropyl, 3-monoisopropylaminopropyl, 2- and 4-monopropylaminobutyl, 2- and 4-dimethylaminobutyl, 6-methyl-3,6-diazaheptyl, 3,6-dimethyl-3,6-diazaheptyl, 3,6-diazaoctyl, 3,6-dimethyl-3,6-diazaoctyl, 9-methyl-3,6,9-triazadecyl, 3,6,9-trimethyl-3,6,9-triazadecyl, 3,6,9-triazaundecyl, 3,6,9-trimethyl-3,6,9-triazaundecyl, 12-methyl-3,6,9,12-tetraazamidecyl and 3,6,9,12-tetramethyl-3,6,9,12-tetraazamidecyl;

(1-ethylethylidene)aminoethylene, (1-ethylethylidene)aminopropylene, (1-ethylethylidene)aminobutylene, (1-ethylethylidene)aminodecylene and (1-ethylethylidene)aminododecylene;

propan-2-on-1-yl, butan-3-on-1-yl, butan-3-on-2-yl and 2-ethylpentan-3-on-1-yl;

2-methylsulfinylethyl, 2-ethylsulfinylethyl, 2-propylsulfinylethyl, 2-isopropylsulfinylethyl, 2-butylsulfinylethyl, 2- and 3-methylsulfinylpropyl, 2- and 3-ethylsulfinylpropyl, 2- and 3-propylsulfinylpropyl, 2- and 3-butylsulfinylpropyl, 2- and 4-methylsulfinylbutyl, 2- and 4-ethylsulfinylbutyl, 2- and 4-propylsulfinylbutyl and 4-butylsulfinylbutyl;

2-methylsulfonylethyl, 2-ethylsulfonylethyl, 2-propylsulfonylethyl, 2-isopropylsulfonylethyl, 2-butylsulfonylethyl, 2- and 3-methylsulfonylpropyl, 2- and 3-ethylsulfonylpropyl, 2- and 3-propylsulfonylpropyl, 2- and 3-butylsulfonylproypl, 2- and 4-methylsulfonylbutyl, 2- and 4-ethylsulfonylbutyl, 2- and 4-propylsulfonylbutyl and 4-butylsulfonylbutyl;

carboxymethyl, 2-carboxyethyl, 3-carboxypropyl, 4-carboxybutyl, 5-carboxypentyl, 6-carboxyhexyl, 8-carboxyoctyl, 10-carboxydecyl, 12-carboxydodecyl and 14-carboxyl-tetradecyl;

sulfomethyl, 2-sulfoethyl, 3-sulfopropyl, 4-sulfobutyl, 5-sulfopentyl, 6-sulfohexyl, 8-sulfooctyl, 10-sulfodecyl, 12-sulfododecyl and 14-sulfotetradecyl;

2-hydroxyethyl, 2- and 3-hydroxypropyl, 3- and 4-hydroxybutyl and 8-hydroxyl-4-oxaoctyl;

2-cyanoethyl, 3-cyanopropyl, 3- and 4-cyanobutyl;

2-chloroethyl, 2- and 3-chloropropyl, 2-, 3- and 4-chlorobutyl, 2-bromoethyl, 2- and

3-bromopropyl and 2-, 3- and 4-bromobutyl;

2-nitroethyl, 2- and 3-nitropropyl and 2-, 3- and 4-nitrobutyl;

methoxy, ethoxy, propoxy, butoxy, pentoxy and hexoxy;

methylthio, ethylthio, propylthio, butylthio, pentylthio and hexylthio;

methylamino, ethylamino, propylamino, butylamino, pentylamino, hexylamino, dicyclopentylamino, dicyclohexylamino, dicycloheptylamino, diphenylamino and dibenzylamino;

formylamino, acetylamino, propionylamino and benzoylamino;

carbamoyl, methylaminocarbonyl, ethylaminocarbonyl, propylaminocarbonyl, butyl-aminocarbonyl, pentylaminocarbonyl, hexylaminocarbonyl, heptylaminocarbonyl, octylaminocarbonyl, nonylaminocarbonyl, decylaminocarbonyl and phenylamino-carbonyl;

aminosulfonyl, n-dodecylaminosulfonyl, N,N-diphenylaminosulfonyl, and N,N-bis(4-chlorophenyl)aminosulfonyl;

methoxycarbonyl, ethoxycarbonyl, propoxycarbonyl hexoxycarbonyl, dodecyloxycarbonyl, octadecyloxycarbonyl, phenoxycarbonyl, (4-tert-butylphenoxy)carbonyl and (4-chlorophenoxy)carbonyl;

methoxysulfonyl, ethoxysulfonyl, propoxysulfonyl, butoxysulfonyl, hexoxysulfonyl, dodecyloxysulfonyl and octadecyloxysulfonyl.

In the context of the invention, cycloalkyl denotes a cycloaliphatic radical having preferably 3 to 10, more preferably 5 to 8, carbon atoms. Examples of cycloalkyl groups are especially cyclopropyl, cyclobutyl, cyclopentyl, cyclohexyl, cycloheptyl or cyclooctyl.

Substituted cycloalkyl groups may, depending on the ring size, have one or more (e.g. 1, 2, 3, 4, or more than 5) substituents. These are preferably each independently selected from alkyl, alkoxy, alkylamino, alkylthio, cycloalkyl, heterocycloalkyl, aryl, hetaryl, fluorine, chlorine, bromine, cyano and nitro. In the case of substitution, the cycloalkyl groups preferably bear one or more, for example one, two, three, four or five, C₁-C₆-alkyl groups. Examples of substituted cycloalkyl groups are especially 2- and 3-methylcyclopentyl, 2- and 3-ethylcyclopentyl, 2-,3- and 4-methylcyclohexyl, 2-, 3- and 4-ethylcyclohexyl, 2-, 3- and 4-propylcyclohexyl, 2-, 3- and 4-isopropylcyclohexyl, 2-, 3- and 4-butylcyclohexyl, 2-, 3- and 4-sec.-butylcyclohexyl, 2-, 3- and 4-tert-butylcyclohexyl, 2-, 3- and 4-methylcycloheptyl, 2-, 3- and 4-ethylcycloheptyl, 2-, 3- and 4-propylcycloheptyl, 2-, 3- and 4-isopropylcycloheptyl, 2-, 3- and 4-butylcycloheptyl, 2-, 3- and 4-sec-butylcycloheptyl, 2-, 3- and 4-tert-butylcycloheptyl, 2-, 3-, 4- and 5-methylcyclooctyl, 2-, 3-, 4- and 5-ethylcyclooctyl, 2-, 3-, 4- and 5-propylcyclooctyl.

Specific examples of substituted and unsubstituted cycloalkyl groups are cyclopropyl, cyclobutyl, cyclopentyl, 2- and 3-methylcyclopentyl, 2- and 3-ethylcyclo-pentyl, cyclohexyl, 2-, 3- and 4-methylcyclohexyl, 2-, 3- and 4-ethylcyclohexyl, 3- and 4-propylcyclohexyl, 3- and 4-isopropylcyclohexyl, 3- and 4-butylcyclohexyl, 3- and 4-sec-butylcyclohexyl, 3- and 4-tert-butylcyclohexyl, cycloheptyl, 2-, 3- and 4-methyl-cycloheptyl, 2-, 3- and 4-ethylcycloheptyl, 3- and 4-propylcycloheptyl, 3- and 4-iso-propylcycloheptyl, 3- and 4-butylcycloheptyl, 3- and 4-sec-butylcycloheptyl, 3- and 4-tert-butylcycloheptyl, cyclooctyl, 2-, 3-, 4- and 5-methylcyclooctyl, 2-, 3-, 4- and 5-ethylcyclooctyl and 3-, 4- and 5-propylcyclooctyl; 3- and 4-hydroxycyclohexyl, 3- and 4-nitrocyclohexyl and 3- and 4-chlorocyclohexyl;

In the context of the present invention, aryl comprises mono- or polycyclic aromatic hydrocarbon radicals and monocyclic aromatic hydrocarbon radicals which may be fused to one or more unfused or fused saturated or unsaturated carbocyclic or heterocyclic five or six membered rings. Aryl has preferably 6 to 14, more preferably 6 to 10, carbon atoms. Examples of aryl are especially phenyl, naphthyl, indenyl, fluorenyl, anthracenyl, phenanthrenyl, naphthacenyl, chrysenyl and pyrenyl, especially phenyl, naphthyl and fluorenyl.

Substituted aryls may, depending on the number and size of their ring systems, have one or more (e.g. 1, 2, 3, 4, 5 or more than 5) substituents. These are preferably each independently selected from alkyl, alkoxy, alkylamino, alkylthio, cycloalkyl, heterocycloalkyl, aryl, hetaryl, fluorine, chlorine, bromine, cyano and nitro. The alkyl, alkoxy, alkylamino, alkylthio, cycloalkyl, heterocycloalkyl, aryl and hetaryl substituents on the aryl may in turn be unsubstituted or substituted. Reference is made to the substituents mentioned above for these groups. The substituents on the aryl are preferably selected from alkyl, alkoxy, haloalkyl, haloalkoxy, aryl, fluorine, chlorine, bromine, cyano and nitro. Substituted aryl is more preferably substituted phenyl which generally bears 1, 2, 3, 4 or 5, preferably 1, 2 or 3, substituents. Substituted aryl is preferably aryl substituted by at least one alkyl group (“alkaryl”). Alkaryl groups may, depending on the size of the aromatic ring system, have one or more (e.g. 1, 2, 3, 4, 5, 6, 7, 8, 9 or more than 9) alkyl substituents. The alkyl substituents may be unsubstituted or substituted. In this regard, reference is made to the above statements regarding unsubstituted and substituted alkyl. In a preferred embodiment, the alkaryl groups have exclusively unsubstituted alkyl substituents. Alkaryl is preferably phenyl which bears 1, 2, 3, 4 or 5, preferably 1, 2 or 3, more preferably 1 or 2, alkyl substituents.

Aryl which bears one or more radicals is, for example, 2-, 3- and 4-methylphenyl, 2,4-, 2,5-, 3,5- and 2,6-dimethylphenyl, 2,4,6-trimethylphenyl, 2-, 3- and 4-ethylphenyl, 2,4-, 2,5-, 3,5- and 2,6-diethylphenyl, 2,4,6-triethylphenyl, 2-, 3- and 4-propylphenyl, 2,4-, 2,5-, 3,5- and 2,6-dipropylphenyl, 2,4,6-tripropylphenyl, 2-, 3- and 4-isopropylphenyl, 2,4-, 2,5-, 3,5- and 2,6-diisopropylphenyl, 2,4,6-triisopropylphenyl, 2-, 3- and 4-butylphenyl, 2,4-, 2,5-, 3,5- and 2,6-dibutylphenyl, 2,4,6-tributylphenyl, 2-, 3- and 4-isobutylphenyl, 2,4-, 2,5-, 3,5- and 2,6-diisobutylphenyl, 2,4,6-triisobutylphenyl, 2-, 3- and 4-sec-butylphenyl, 2,4-, 2,5-, 3,5- and 2,6-di-sec-butylphenyl, 2,4,6-tri-sec-butylphenyl, 2-, 3- and 4-tert-butylphenyl, 2,4-, 2,5-, 3,5- and 2,6-di-tert-butylphenyl and 2,4,6-tri-tert-butylphenyl; 2-, 3- and 4-methoxyphenyl, 2,4-, 2,5-, 3,5- and 2,6-dimethoxyphenyl, 2,4,6-trimethoxyphenyl, 2-, 3- and 4-ethoxyphenyl, 2,4-, 2,5-, 3,5- and 2,6-diethoxyphenyl, 2,4,6-triethoxyphenyl, 2-, 3- and 4-propoxyphenyl, 2,4-, 2,5-, 3,5- and 2,6-dipropoxyphenyl, 2-, 3- and 4-isopropoxyphenyl, 2,4-, 2,5-, 3,5- and 2,6-diisopropoxyphenyl and 2-, 3- and 4-butoxyphenyl; 2-, 3- and 4-cyanophenyl.

The above remarks regarding unsubstituted or substituted aryl also apply to unsubstituted or substituted aryloxy and unsubstituted or substituted arylthio. Examples of aryloxy are phenoxy and naphthyloxy.

In the context of the present invention, hetaryl comprises heteroaromatic, mono- or polycyclic groups and monocyclic groups which may be fused to one or more unfused or fused saturated or unsaturated carbocyclic or heterocyclic five or six membered rings. In addition to the ring carbon atoms, these have 1, 2, 3, 4 or more than 4 of the ring heteroatoms. The heteroatoms are preferably selected from oxygen, nitrogen, selenium and sulfur. The hetaryl groups have preferably 5 to 18, e.g. 5, 6, 8, 9, 10, 11, 12, 13 or 14, ring atoms.

Monocyclic hetaryl groups are preferably 5- or 6-membered hetaryl groups, such as 2-furyl (furan-2-yl), 3-furyl (furan-3-yl), 2-thienyl (thiophen-2-yl), 3-thienyl (thiophen-3-yl), selenophen-2-yl, selenophen-3-yl, 1H-pyrrol-2-yl, 1H-pyrrol-3-yl, pyrrol-1-yl, imidazol-2-yl, imidazol-1-yl, imidazol-4-yl, pyrazol-1-yl, pyrazol-3-yl, pyrazol-4-yl, pyrazol-5-yl, 3-isoxazolyl, 4-isoxazolyl, 5-isoxazolyl, 3-isothiazolyl, 4-isothiazolyl, 5-isothiazolyl, 2-oxazolyl, 4-oxazolyl, 5-oxazolyl, 2-thiazolyl, 4-thiazolyl, 5-thiazolyl, 1,2,4-oxadiazol-3-yl, 1,2,4-oxadiazol-5-yl, 1,3,4-oxadiazol-2-yl, 1,2,4-thiadiazol-3-yl, 1,2,4-thiadiazol-5-yl, 1,3,4-thiadiazol-2-yl, 4H[1,2,4]-triazol-3-yl, 1,3,4-triazol-2-yl, 1,2,3-triazol-1-yl, 1,2,4-triazol-1-yl, pyridin-2-yl, pyridin-3-yl, pyridin-4-yl, 3-pyridazinyl, 4-pyridazinyl, 2-pyrimidinyl, 4-pyrimidinyl, 5-pyrimidinyl, 2-pyrazinyl, 1,3,5-triazin-2-yl and 1,2,4-triazin-3-yl.

Polycyclic hetaryl has 2, 3, 4 or more than 4 fused rings. The fused-on rings may be aromatic, saturated or partly unsaturated. Examples of polycyclic hetaryl groups are quinolinyl, isoquinolinyl, indolyl, isoindolyl, indolizinyl, benzofuranyl, isobenzofuranyl, benzothiophenyl, benzoxazolyl, benzisoxazolyl, benzthiazolyl, benzoxadiazolyl; benzothiadiazolyl, benzoxazinyl, benzopyrazolyl, benzimidazolyl, benzotriazolyl, benzotriazinyl, benzoselenophenyl, thienothiophenyl, thienopyrimidyl, thiazolothiazolyl, dibenzopyrrolyl (carbazolyl), dibenzofuranyl, dibenzothiophenyl, naphtho[2,3-b]thiophenyl, naphtha[2,3-b]furyl, dihydroindolyl, dihydroindolizinyl, dihydroisoindolyl, dihydroquinolinyl, dihydroisoquinolinyl.

Substituted heteroaryls may, depending on the number and size of their ring systems, have one or more (e.g. 1, 2, 3, 4, 5 or more than 5) substituents. These are preferably each independently selected from alkyl, alkoxy, alkylamino, alkylthio, cycloalkyl, heterocycloalkyl, aryl, hetaryl, fluorine, chlorine, bromine, cyano and nitro. Halogen substituents are preferably fluorine, chlorine or bromine. The substituents are preferably selected from C₁-C₆-alkyl, C₁-C₆-alkoxy, hydroxyl, carboxyl, halogen and cyano.

The above remarks regarding unsubstituted or substituted heteroaryl also apply to unsubstituted or substituted heteroaryloxy and unsubstituted or substituted heteroarylthio.

Further details on the preparation of the compounds according to the instant invention can be taken from the experimental section.

DSCs generally comprise the following elements: an electrically conductive layer (being part of or forming the working electrode or anode), a photosensitive layer generally comprising a semiconductive metal oxide and a photosensitive dye, a charge transfer layer and another electrically conductive layer (being part of or forming the counter electrode or cathode).

Regarding further details of the construction of DSCs particular reference is made to WO 2012/001628 A1, which is hereby fully incorporated by reference.

### EXPERIMENTAL PART

### A1) Preparation of Compounds or General Formula I According to the Invention

Utilizing the Buchwald-Hartwig C-N cross-coupling reaction, corresponding diphenylamines M1-M3 were synthesized from respective aromatic amines and aryl halides. Palladium catalyzed reaction of these diphenylamines M1-M3 with 2,2′,7,7′-tetrabromo-9,9′-spirobifluorene (e.g. commercially available from TCI EUROPE N.V. 2070 Zwijndrecht, Belgium) yielded target hole transporting materials HTM1, HTM2 and HTM3.

### Example 1

### Preparation of HTM1

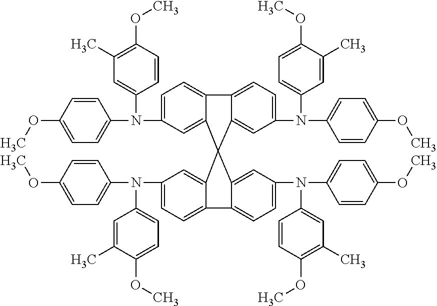

### a) Preparation of 4,4′-dimethoxy-3-methyldiphenylamine (M1)

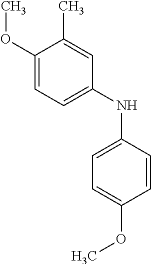 [SMILES: COc1ccc(Nc2ccc(OC)c(C)c2)cc1]

A mixture of dioxane (12 ml) and water (0.004 g, 0.22 mmol) was purged with argon for 20 minutes. Pd(OAc)₂ (0.014 g, 0.06 mmol) and 2-dicyclohexylphosphino-2′,4′,6′-triisopropylbiphenyl (“XPhos”; 0.086 g, 0.18 mmol) were added and the mixture was heated to 80° C. for 90 seconds. Afterwards 5-bromo-2-methoxytoluene (2.44 g, 12.1 mmol), 4-methoxyaniline (1.79 g, 14.5 mmol) and NaOt-Bu (1.64 g, 17.1 mmol) were added and the mixture was stirred at 110° C. for 15 minutes. After termination of the reaction (monitored via TLC, acetone:n-hexane=1:4, v/v) the mixture was diluted with ethyl acetate and washed with water. The organic layer was dried over anhydrous Na₂SO₄, filtered and the solvent removed. The residue was purified by column chromatography using acetone: n-hexane (0.5:24.5, v/v) as eluent. The product was obtained as whitish crystals (2.7 g, 92%). Melting point: 55-56.5° C.

¹H NMR (300 MHz, CDCl₃), δ (ppm): 6.94 (d, J=9.0 Hz, 2H), 6.82 (m, 4H), 6.73 (d, J=9.0 Hz, 1H), 5.24 (s, 1H, NH), 3.79 (s, 3H, OCH₃), 3.77 (s, 3H, OCH₃), 2.18 (s, 3H, CH₃)

¹³C NMR (75 MHz, CDCl₃), δ (ppm): 154.22, 152.67, 138.22, 137.58, 127.74, 121.59, 119.58, 116.40, 114.80, 111.19, 55.92, 55.76, 16.46

Elemental analysis calculated for C₁₅H₁₇NO₂: 74.05% C, 7.04% H, 5.76% N. found: 74.12% C, 7.11% H, 5.68% N.

### b) Preparation of HTM1

A mixture of 2,2′,7,7′-tetrabromo-9,9′-spirobifluorene (0.28 g, 0.44 mmol) and M1 (0.75 g, 3.08 mmol) in dry toluene (5 ml) was purged with argon for 30 minutes. Pd(OAc)₂ (0.002 g, 0.009 mmol), tri-tert-butylphosphonium tetrafluoroborate (0.004 g, 0.013 mmol) and NaOt-Bu (0.25 g, 2.60 mmol) were added and the mixture was refluxed for 4 hours. After termination of the reaction (monitored via TLC, acetone:n-hexane=7:18, v/v) the mixture was diluted with toluene, filtered through Celite® and extracted with water. The organic layer was dried over anhydrous Na₂SO₄, filtered and the solvent removed. The residue was purified by column chromatography using acetone: n-hexane (1:24 and 2:23, v/v) as eluent and then precipitated from a 20% solution in acetone into a 10-fold excess of methanol. The precipitate was filtered off and washed with methanol to give 0.45 g (80%) of pale yellow solid

¹H NMR (300 MHz, CDCl₃), δ (ppm): 7.33 (d, J=7.8 Hz, 4H), 7.17-6.21 (m, 36H), 3.75 (s, 24H, OCH₃), 2.10 (s, 12H, CH₃)

¹³C NMR (75 MHz, CDCl₃), δ (ppm): 155.21, 153.70, 150.12, 127.42, 125.20, 122.37, 119.80, 117.74, 114.44, 110.66, 55.76, 16.40

Elemental analysis calculated for C₈₅H₇₆N₄O₈: 79.66% C, 5.98% H, N, 4.37. found: 79.61% C, 6.02% H, 4.41% N.

### Example 2

### Preparation of HTM2

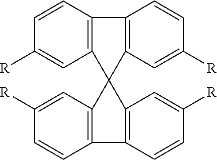

where R denotes moieties

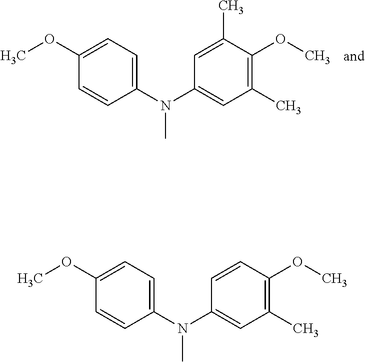

in equimolar proportions and randomized distribution.

### a) Preparation of 4,4′-Dimethoxy-3,5-dimethyldiphenylamine (M2)

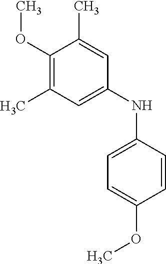 [SMILES: COc1ccc(Nc2cc(C)c(OC)c(C)c2)cc1]

A mixture of dioxane (6.5 ml) and water (0.002 g, 0.11 mmol) was purged with argon for 20 minutes. Pd(OAc)₂ (0.007 g, 0.031 mmol) and 2-dicyclohexylphosphino-2′,6′-dimethoxybiphenyl (“SPhos”; 0.04 g, 0.097 mmol) were added and the mixture was heated to 80° C. for 90 seconds. Afterwards 4-iodo-1,3-dimethyl-2-methoxybenzene (1.7 g, 6.49 mmol), 4-methoxyaniline (0.96 g, 7.80 mmol) and NaOt-Bu (0.88 g, 9.12 mmol) were added and the mixture was stirred at 110° C. for 15 minutes. After termination of the reaction (monitored via TLC, acetone:n-hexane=1:4, v/v) the mixture was diluted with ethyl acetate and washed with water. The organic layer was dried over anhydrous Na₂SO₄, filtered and the solvent removed. The residue was purified by column chromatography using acetone: n-hexane (0.9:24.1, v/v) as eluent. The product was obtained as pale brown solid (1.60 g, 96%). Melting point: 84-85° C.

¹H NMR (300 MHz, CDCl₃), δ (ppm): 7.02 (d, J=9.0 Hz, 2H), 6.86 (d, J=9.0 Hz, 2H), 6.60 (s, 2H), 5.30 (s, 1H, NH), 3.80 (s, 3H, OCH₃), 3.69 (s, 3H, OCH₃), 2.24 (s, 6H, CH₃)

¹³C NMR (75 MHz, CDCl₃), δ (ppm): 154.85, 150.76, 140.72, 136.89, 131.67, 121.30, 116.75, 114.78, 60.07, 55.72, 16.35

Elemental analysis calculated for C₁₆H₁₉NO₂: 74.68% C, 7.44% H, 5.44% N. found: 74.61% C, 7.49 H, 5.48% N.

### b) Preparation of HTM2

A mixture of 2,2′,7,7′-tetrabromo-9,9′-spirobifluorene (0.50 g, 0.79 mmol), M1 (0.41 g, 1.67 mmol) and M2 (0.43 g, 1.67 mmol) in dry toluene (10 ml) was purged with argon for 30 minutes. Pd(OAc)₂ (0.004 g, 0.018 mmol), tri-tert-butylphosphonium tetrafluoroborate (0.006 g, 0.021 mmol) and NaOt-Bu (0.46 g, 4.79 mmol) were added and the mixture was refluxed for 2 hours. After termination of the reaction (monitored via TLC, acetone:n-hexane=1:4, v/v) the mixture was diluted with toluene, filtered through Celite® and extracted with water. The organic layer was dried over anhydrous Na₂SO₄, filtered and the solvent removed. The residue was purified by column chromatography using acetone:n-hexane (2:23 and 3:22, v/v) as eluent and then precipitated from a 20% solution in toluene into 10-fold excess of n-hexane. The precipitate was filtered off and washed with n-hexane to give (0.75 g, 72%) of a pale yellow solid.

MS (APCI⁺, 20V) m/z: 1281, 1295, 1309, 1323, 1337 [M+H]⁺.

### Example 3

### Preparation of HTM3

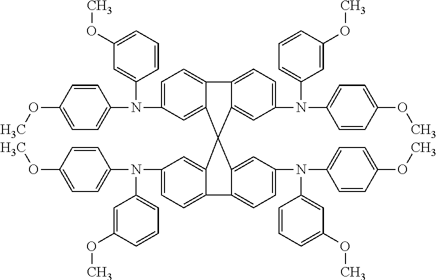

### a) Preparation of 3,4′-Dimethoxydiohenylamine (M3)

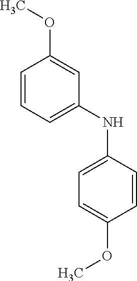 [SMILES: COc1ccc(Nc2cccc(OC)c2)cc1]

A mixture of dioxane (10 ml) and water (0.004 g, 0.22 mmol) was purged with argon for 20 minutes. Pd(OAc)₂ (0.011 g, 0.049 mmol) and 2-dicyclohexylphosphino-2′,6′-dimethoxybiphenyl (“SPhos”; 0.062 g, 0.15 mmol) were added and the mixture was heated to 80° C. for 90 seconds. Afterwards 4-methoxyiodobenzene (2.34 g, 10 mmol), 3-methoxyaniline (1.47 g, 11.94 mmol) and NaOt-Bu (1.35 g, 14.05 mmol) were added and the mixture was stirred at 110° C. for 20 minutes. After termination of the reaction (monitored via TLC, acetone:n-hexane=1:4, v/v) the mixture was diluted with ethyl acetate and washed with water. The organic layer was dried over anhydrous Na₂SO₄, filtered and the solvent removed. The residue was purified by column chromatography using acetone: n-hexane (0.5:24.5, v/v) as eluent. The product was obtained as whitish crystals (1.89 g, 96%). Melting point: 66-67.5° C.

¹H NMR (300 MHz, CDCl₃), δ (ppm): 7.12 (m, 1H), 7.08 (d, J=9.0 Hz, 2H), 6.86 (d, J=9.0 Hz, 2H), 6.51-6.44 (m, 2H), 6.41-6.35 (m, 1H), 5.50 (s, 1H, NH), 3.79 (s, 3H, OCH₃), 3.74 (s, 3H, OCH₃)

¹³C NMR (75 MHz, CDCl₃), δ (ppm): 160.87, 155.55, 146.81, 135.50, 130.18, 122.82, 114.76, 108.41, 104.79, 101.39, 55.67, 55.26

Elemental analysis calculated for C₁₄H₁₅NO₂: 73.34% C, 6.59% H, 6.11% N. found: 73.42% C, 6.63% H, 6.14% N.

### b) Preparation of HTM3

A mixture of 2,2′,7,7′-tetrabromo-9,9′-spirobifluorene (0.4 g, 0.63 mmol) and 3,4′-dimethoxydiphenylamine (0.88 g, 3.84 mmol) in dry toluene (6 ml) was purged with argon for 30 minutes. Pd(OAc)₂ (0.003 g, 0.013 mmol), tri-tert-butylphosphonium tetrafluoroborate (0.005 g, 0.017 mmol), and NaOt-Bu (0.36 g, 3.75 mmol) were added and the mixture was refluxed for 3 hours. After termination of the reaction (monitored via TLC, acetone:n-hexane=1:4, v/v) the mixture was diluted with toluene, filtered through Celite® and extracted with water. The organic layer was dried over anhydrous Na₂SO₄, filtered and the solvent removed. The residue was purified by column chromatography using acetone:n-hexane (7:18, v/v) as eluent and then precipitated from a 20% solution in acetone into 10-fold excess of methanol. The precipitate was filtered off and washed with methanol to give 0.60 g (77%) of yellow solid.

¹H NMR (300 MHz, CDCl₃), δ (ppm): 7.45 (d, J=7.8 Hz, 4H), 7.07 (t, J=9.0 Hz, 4H), 6.99 (d, J=9.0 Hz, 8H), 6.90 (d, J=7.8 Hz, 4H), 6.82 (d, J=9.0 Hz, 8H), 6.67 (d, J=1.8 Hz, 4H), 6.50-6.39 (m, 12H), 3.79 (s, 12H, OCH₃), 3.65 (s, 12H, OCH₃)

¹³C NMR (75 MHz, CDCl₃), δ (ppm): 160.40, 156.10, 146.82, 140.67, 136.37, 129.60, 126.94, 124.13, 120.23, 119.36, 114.73, 114.28, 108.08, 107.66, 106.72, 67.79, 55.55, 55.26

Elemental analysis calculated for C₈₁H₆₈N₄O₈: 79.39% C, 5.59% H, 4.57% N. found: 79.48% C, 5.65% H, 4.63% N.

### B) Preparation and characterization of the DSCs

### General Methods and Materials

Preparation of the Solid-State Dye-Sensitized Solar-Cells: A TiO₂ blocking layer was prepared on a fluorine-doped tin oxide (FTO)-covered glass substrate using spray pyrolysis (cf. B. Peng, G. Jungmann, C. Jager, D. Haarer, H. W. Schmidt, M. Thelakkat, Coord. Chem. Rev. 2004, 248, 1479). Next, a TiO₂ paste (Dyesol), diluted with terpineol, was applied by screen printing, resulting in a film thickness of 1.7 μm. All films were then sintered for 45 min at 450° C., followed by treatment in a 40 mM aqueous solution of TiCl₄ at 60° C. for 30 min, followed by another sintering step. The prepared samples with TiO₂ layers were pretreated with a 5 mM solution of the additive 2-(p-butoxyphenyl)acetohydroxamic acid sodium salt (“ADD1”) in ethanol (this additive is described on page 52 of WO 2012/001628 A1 as “Example No. 6”). The electrodes were then dyed in 0.5 mM dye solution in CH₂Cl₂. The hole transporting material spiro-MeOTAD (commercially availble from Merck KGaA, Darmstadt as SHT-263 Livilux®) and compounds HTM1, HTM2 and HTM3 were applied by spin-coating from a solution in DCM (200 mg/mL) also containing 20 mM Li(CF₃SO₂)₂N. Fabrication of the device was completed by evaporation of 200 nm of silver as the counter electrode. The active area of the sDSC was defined by the size of these contacts (0.13 cm²), and the cells were masked by an aperture of the same area for measurements. The Current-voltage characteristics for all cells were measured with a Keithley 2400 under 1000 W/m², AM 1.5G conditions (LOT ORIEL 450 W). The incident photon to current conversion efficiency's (IPCE) were obtained with an Acton Research Monochromator using additional white background light illumination.

The samples were illuminated with monochromatic light from the quartz monochromator with deuterium lamp. The power of the incident light beam was (2-5).10⁻⁸ W. The negative voltage of −300 V was supplied to the sample substrate. The counter-electrode with the 4.5×15 mm² slit for illumination was placed at 8 mm distance from the sample surface. The counter-electrode was connected to the input of the BK2-16 type electrometer, working in the open input regime, for the photocurrent measurement. The 10⁻¹⁵-10⁻¹² A strong photocurrent was flowing in the circuit under illumination. The photocurrent J is strongly dependent on the incident light photon energy hv. The J^{0.5}=f(hν) dependence was plotted. Usually the dependence of the photocurrent on incident light quanta energy is well described by linear relationship between J^{0.5} and hv near the threshold (cf. E. Miyamoto, Y. Yamaguchi, M. Yokoyama, Electrophotography 1989, 28, 364 and M. Cordona, L. Ley, Top. Appl. Phys. 1978, 26, 1). The linear part of this dependence was extrapolated to the hν axis and Jₚ value was determined as the photon energy at the interception point.

The results of the DSCs with varying hole transporting materials (“HTM”) are given in the following table and correspond to AM1.5 standard conditions at 25° C.

| HTM | V_{OC} in mV | I_{SC} in mA/cm² | FF in % | η in % |
|---|---|---|---|---|
| HTM1 | 820 | −9.34 | 63 | 4.8 |
| HTM2 | 700 | −10 | 48 | 3.4 |
| HTM3 | 880 | −6.19 | 37 | 2 |
| spiro-MeOTAD | 740 | −10.48 | 54 | 4.1 |

(V_{OC}: Open circuit voltage; I_{SC}: Short circuit current; FF: Fill Factor; η: Efficiency)

The results of the following table were gained at AM1.5 standard conditions and 60° C. at the start of the lifetime tests (values correspond to FIG. 1 where the lifetime is equal to 0 (zero) hours):

| HTM | V_{OC} in mV | I_{SC} in mA/cm² | FF in % | η in % |
|---|---|---|---|---|
| HTM1 | 740 | −7.27 | 48 | 2.6 |
| HTM2 | 700 | −10.00 | 48 | 3.4 |
| HTM3 | 800 | −4.01 | 41 | 1.3 |
| spiro-MeOTAD | 860 | −8.70 | 69 | 5.1 |

1. A 9,9′-spirobifluorene compound of formula (I): 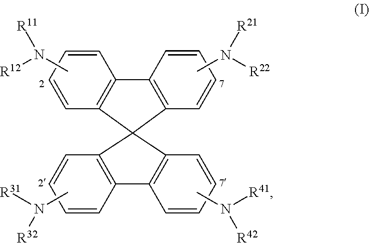
wherein R¹¹, R¹², R²¹, R²², R³¹, R³², R⁴¹ and R⁴² are each independently an aryl or a hetaryl, with the proviso that not all of the radicals R¹¹, R¹², R²¹, R²², R³¹, R³², R⁴¹, and R⁴² are identical.

2. The compound according to claim 1, wherein, in formula (I), the moieties N(R¹¹R¹²), N(R²¹R²²), N(R³¹R³²), and N(R⁴¹R⁴²) are bound to the 2, 2′,7, and 7′ positions of the 9,9′-spirobifluorene skeleton.

3. The compound according to claim 1, wherein, in formula (I), R¹¹, R¹², R²¹, R²², R³¹, R³², R⁴¹ and R⁴², are each independently a moiety of formulae (Ia) or (Ib): 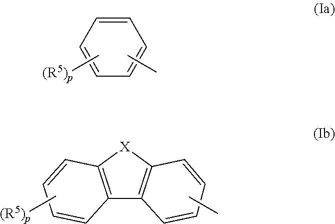
wherein:
R⁵ is hydrogen, alkyl, aryl, alkoxy, alkylthio, or —NR⁶R⁷, wherein plural R⁵s may be identical or different;
p is 0, 1, 2, 3, 4, or 5;
X is C(R⁸R⁹)₂, NR¹⁰, oxygen, or sulfur; and
R⁶, R⁷, R⁸, R⁹, and R¹⁰ are each independently hydrogen, alkyl, cycloalkyl, aryl, or hetaryl.

4. The compound according to claim 1, wherein, in formula (I), R¹¹, R², R³¹, and R⁴¹ are identical to each other and R¹², R²², R³², and R⁴² are identical to each other.

5. An organic electronic device, comprising a compound of formula (I) according to claim 1.

6. The organic electronic device of 5, which is an organic field effect transistor.

7. The organic electronic device of 5, which is an organic solar cell.

8. A dye-sensitized solar cell comprising a compound of formula (I) according to claim 1.

9. A bulk heterojunction solar cell comprising a compound of formula (I) according to claim 1.

10. The organic electronic device of claim 5, which is an organic photodetector.
